(19) United States
(12) Patent Application Publication
(10) Pub. No.: US 2008/0123176 A1
(43) Pub. Date: May 29, 2008

(54) PROCESS FOR CREATING OHMIC CONTACT

(75) Inventor: Anthony DiCarlo, Richardson, TX (US)

Correspondence Address: TEXAS INSTRUMENTS INCORPORATED, P O BOX 655474, M/S 3999, DALLAS, TX, 75265, US

(73) Assignee: Texas Instruments, Incorporated, Dallas, TX (US)

(21) Appl. No.: 11/467,979

(22) Filed: Aug. 29, 2006

(51) Int. Cl. G02B 26/00; H01L 21/00

(52) U.S. Cl. 359/291; 438/50; 257/E21.001; 438/734

(57) ABSTRACT

The present invention provides a method for manufacturing a microelectronic device and a microelectronic device. The method for manufacturing the microelectronic device, without limitation, may include providing a spacer layer over a substrate, the spacer layer having one or more openings therein, and forming a first conductive layer over the spacer layer and within the one or more openings. The method may further include subjecting the first conductive layer to an anisotropic etch, the anisotropic etch exposing at least a portion of the substrate within the one or more openings, but leaving the spacer layer substantially covered, and forming a second conductive layer over the first conductive layer and within the one or more openings, the second conductive layer contacting the substrate exposed by the anisotropic etch.

### TECHNICAL FIELD OF THE INVENTION

The present invention is directed, in general, to a microelectronic device and, more specifically, to a process for creating ohmic contact in a microelectronic device and a microelectronic device having ohmic contact.

### BACKGROUND OF THE INVENTION

A Digital Micromirror Device (DMD) is a type of micro-electro-mechanical systems (MEMS) device. Invented in 1987 at Texas Instruments Incorporated, the DMD is a fast, reflective digital light switch. It can be combined with image processing, memory, a light source, and optics to form a digital light processing® system capable of projecting large, bright, high-contrast color images.

The DMD is fabricated using CMOS-like processes over a CMOS memory. It has an array of individually addressable mirror elements, each having a mirror that can reflect light in one of a plurality of directions depending on the state of an underlying memory cell. By combining the DMD with a suitable light source and projection optics, the mirror reflects incident light either into or out of the pupil of the projection lens. Thus, the first state of the mirror appears bright and the second state of the mirror appears dark. Gray scale is achieved by binary pulse width modulation of the incident light. Color is achieved by using color filters, either stationary or rotating, in combination with one, two, or three DMD chips.

DMD's may have a variety of designs, and the most popular design in current use is a structure consisting of a mirror that is rigidly connected to an underlying yoke. The yoke in turn is connected by two thin, mechanically compliant torsion hinges to support posts that are attached to the underlying substrate. Electrostatic fields developed between the underlying memory cell and the mirror cause rotation in the positive or negative rotation direction.

The fabrication of the above-described DMD superstructure begins with a completed CMOS memory circuit. Through the use of photoresist layers, the superstructure is formed with alternating layers of aluminum for the address electrode, hinge, yoke, and mirror layers and hardened photoresist for sacrificial layers that form air gaps. Unfortunately, the manufacture of the elements of the superstructure may be difficult.

Accordingly, what is needed in the art is a method for manufacturing a microelectronic device, such as a DMD, that does not experience the drawbacks of the prior art methods.

### SUMMARY OF THE INVENTION

To address the above-discussed deficiencies of the prior art, the present invention provides a method for manufacturing a microelectronic device and a microelectronic device. The method for manufacturing the microelectronic device, without limitation, may include providing a spacer layer over a substrate, the spacer layer having one or more openings therein, and forming a first conductive layer over the spacer layer and within the one or more openings. The method may further include subjecting the first conductive layer to an anisotropic etch, the anisotropic etch exposing at least a portion of the substrate within the one or more openings, but leaving the spacer layer substantially covered, and forming a second conductive layer over the first conductive layer and within the one or more openings, the second conductive layer contacting the substrate exposed by the anisotropic etch.

As briefly mentioned, the present invention also discloses a microelectronic device. The microelectronic device, among other features, may include: 1) a conductive feature, 2) a first conductive layer located over the conductive feature, wherein at least a portion of the first conductive layer is configured as a well, and further wherein the first conductive layer has a void in a bottom and about an inner periphery of the well, and 3) a second conductive layer located within the well and substantially filling the void, the second conductive layer configured to form an ohmic contact with the conductive feature.

### BRIEF DESCRIPTION OF THE DRAWINGS

For a more complete understanding of the present invention, reference is now made to the following descriptions taken in conjunction with the accompanying drawings, in which:

FIGS. 1-7 illustrate sectional views showing how one might, in an embodiment, manufacture a DMD in accordance with the principles of the present invention;

FIG. 8 illustrates an exploded view of a completed digital micromirror device manufactured in accordance with the principles of the present invention; and

FIG. 9 illustrates a schematic of a projection display system manufactured in accordance with the principles of the present invention.

### DETAILED DESCRIPTION

The present invention is based, at least in part, on the acknowledgement that ohmic contacts, particularly in Digital Micromirror Devices (DMDs), are difficult to obtain. For example, the present invention has acknowledged that many DMDs lack an ohmic contact between the hinge structure and the initial conductive layer, as well as between the mirror structure and the hinge structure. The present invention has further acknowledged that conventional pre-metal deposition cleans may not be used with to obtain the ohmic contact in such structures, as the pre-metal deposition cleans tend to destroy the photoresist support structures used within the DMDs.

Based upon the foregoing, as well as substantial experimentation, the present invention has recognized that a multi-step deposition process can be used to form the layer needing ohmic contact. This multi-step deposition process would allow the first deposited layer to substantially cover (e.g., protect) the photoresist support structures, while a subsequent etch and latter deposited layer could be used to make the ohmic contact with the conductive layer located therebelow. For example, in one particular embodiment wherein a via has been formed within the photoresist support structure, the first deposited layer could be formed using a short throw distance target, such that the first deposited layer is much thinner about an inner periphery of a bottom of the via than it is on an upper surface of the photoresist layer. Thereafter, this structure could be subjected to an anisotropic etch, thereby exposing at least a portion of the conductive layer located below the via. After the anisotropic etch, the later deposited layer could be deposited using a longer throw distance target to make an ohmic contact with the conductive layer.

At this point, it is important to define certain terms used within this document. Accordingly, the term ohmic contact as used herein means a region on a semiconductor device that has been prepared so that the current-voltage (I-V) curve of the region is linear and symmetric. If the I-V characteristic is non-linear and asymmetric, the contact can instead be termed a blocking or Schottky contact. Additionally, the term substantially cover(ed) means that the photoresist layer is covered enough such that it is not materially affected by any pre-metal deposition cleans, for example the anisotropic etch used herein. Accordingly, while the first conductive layer formed over the photoresist layer may have pin hole or other small defects, the defects are insufficient to allow any pre-metal deposition cleans to materially affect the photoresist layer.

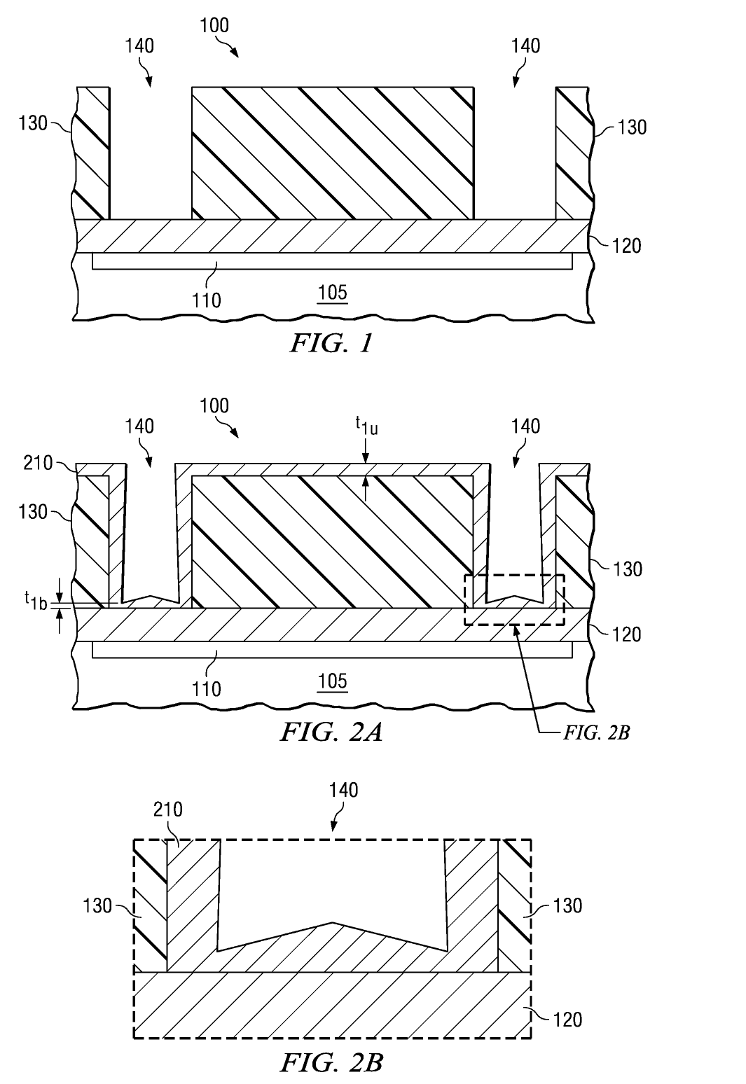

Turning initially to FIGS. 1-7, shown are sectional views illustrating how one might, in an embodiment, manufacture a DMD 100 in accordance with the principles of the present invention. FIG. 1 illustrates the DMD 100 at an initial stage of manufacture. The DMD 100 of FIG. 1 includes control circuitry 110 formed on or in a substrate 105. The substrate 105 may comprise a number of different materials while staying within the scope of the present invention. In the embodiment illustrated in FIG. 1, however, the substrate 105 is epitaxial silicon.

The control circuitry 110 preferably comprises a plurality of CMOS devices, and in one embodiment, addressable SRAM circuits within the substrate 105. Nevertheless, other embodiments may exist wherein additional or different circuitry may be included within the control circuitry 110. While not shown, the DMD 100 may further include an insulating layer formed over the control circuitry. The insulating layer preferably comprises an oxide such as silicon oxide that has been planarized by chemical mechanical planarization.

Located over the substrate 105 is a conductive feature 120. The conductive feature 120 preferably comprises aluminum or aluminum alloy that has been sputter deposited to a thickness ranging from about 100 nm to about 400 nm. While not shown in FIG. 1, vias would typically be formed in the insulating layer to allow the conductive feature 120 to contact the underlying control circuitry 110, where necessary. The conductive feature 120 may also be patterned, resulting in electrode pads and a bias bus. Preferably the conductive feature 120 is patterned by plasma-etching using plasma-deposited silicon dioxide as the etch mask.

Positioned over the substrate 105, the control circuitry 110, and the conductive feature 120 is a first spacer layer 130. As is illustrated, the first spacer layer 130 typically has one or more openings 140 located therein. For example, in one embodiment the first spacer layer 130 is formed by spin depositing a photoresist (e.g., a material that would be materially affected by a pre-metal deposition clean if subjected thereto) to a thickness ranging from about 400 nm to about 1500 nm. Thereafter, the one or more openings 140 may be formed within the first spacer layer 130.

Conventional patterning and etching techniques may be used to form the openings 140 in the first spacer layer 130. For example, the openings 140 may be patterned into the first spacer layer 130 by exposing, patterning, developing and then descuming the first spacer layer 130. After patterning the openings 140 into the first spacer layer 130, the first spacer layer 130 may be deep UV hardened to a temperature of about 200° C. to prevent flow and bubbling during subsequent processing steps.

Turning now to FIGS. 2A and 2B, illustrated is the DMD 100 of FIG. 1 after forming a first conductive layer 210 over the first spacer layer 130 and within the openings 140. It is desirable for the first conductive layer 210 to substantially cover the first spacer layer 130, including substantially covering the tops and sidewalls of the first spacer layer 130, and thereby forming a well of sorts. The first conductive layer 210, in one embodiment, is a first metal layer comprising aluminum. Nevertheless, the first conductive layer 210 may comprise other materials. In the embodiment shown, the first conductive layer 210 forms at least a portion of a hinge metal layer, also referred to as a binge metal layer, as might be used in a DMD structure.

The first conductive layer 210, in the embodiment shown, has a thickness (t₁ᵤ) on an upper surface of the first spacer layer 130 and a thickness (t_{1b}) in a bottom and about an inner periphery of the openings 140. In one embodiment, the thickness (t_{1b}) is less than about 50 percent of the thickness (t₁ᵤ), and in another embodiment the thickness (t_{1b}) is less than about 20 percent of the thickness (t₁ᵤ). For example, in one embodiment the thickness (t_{1b}) might range from about 2.0 nm to about 4.0 nm, wherein the thickness (t₁ᵤ) might range from about 15.0 nm to about 25.0 nm. It should be noted that the difference in thickness, particularly the lesser thickness of (t_{1b}) as compared to (t₁ᵤ), is an important aspect of the present invention.

The first conductive layer 210 illustrated in FIGS. 2A and 2B may be formed using various different processes. In one embodiment, however, the first conductive layer 210 is sputter deposited. For example, the first conductive layer 210 may be sputter deposited using a short throw distance target (e.g., as compared to the longer throw distance target used to form the second conductive layer 410). The aforementioned short throw distance target is at least partially responsible for the first conductive layer 210 having the different thicknesses (t₁ᵤ) and (t_{1b}) discussed above. It is believed that the shorter the throw distance, the greater the disparity between the thicknesses (t₁ᵤ) and (t_{1b}). Accordingly, in one embodiment the shorter throw distance is set to about 100 mm or less.

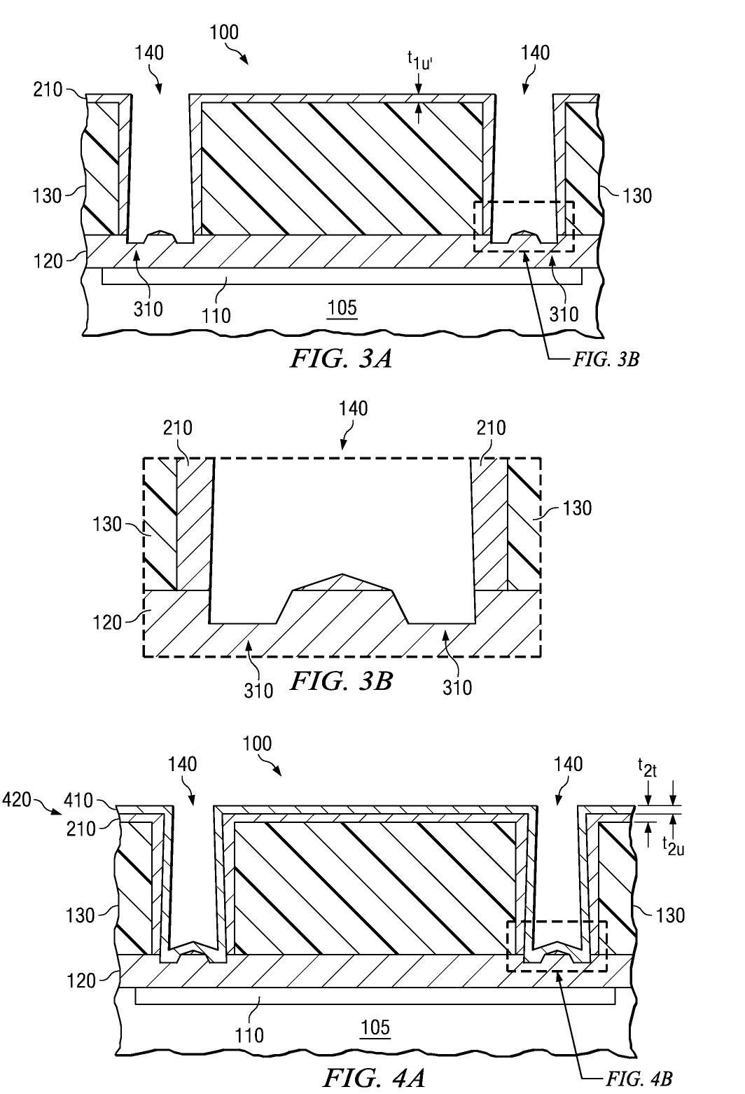

Turning now to FIGS. 3A and 3B, illustrated is the DMD 100 of FIGS. 2A and 2B after subjecting it to an anisotropic etch. The anisotropic etch, as illustrated, exposes at least a portion of the conductive feature 120 within the one or more openings 140, for example creating a void 310, but leaves the first spacer layer 130 substantially covered. In the given embodiment of FIGS. 3A and 3B, the anisotropic etch is conducted so as to expose a ring of the conductive feature 120 in the bottom and about the inner periphery of the openings 140. Particularly, the anisotropic etch is conducted to expose the conductive feature 120 covered by the thinnest sections of the first conductive layer 210, but leave the first spacer layer 130 substantially covered. Because of the aforementioned disparity in thicknesses (t₁ᵤ) and (t_{1b}), as well as the anisotropic nature of the etch, the conductive feature 120 may be exposed without uncovering the first spacer layer 130. In one embodiment, the thickness (t_{1u′}) resulting after the anisotropic etch might be about 50 percent of the original thickness (t₁ᵤ). Accordingly, the thickness (t_{1u′}) might range from about 7.5 nm to about 12.5 nm, among others.

Those skilled in the art understand the myriad of anisotropic etches that might be used to accomplish the foregoing anisotropic etch. In one example, however, the first conductive layer 210 is subjected to an etch for a period of time sufficient to only expose the conductive feature 120.

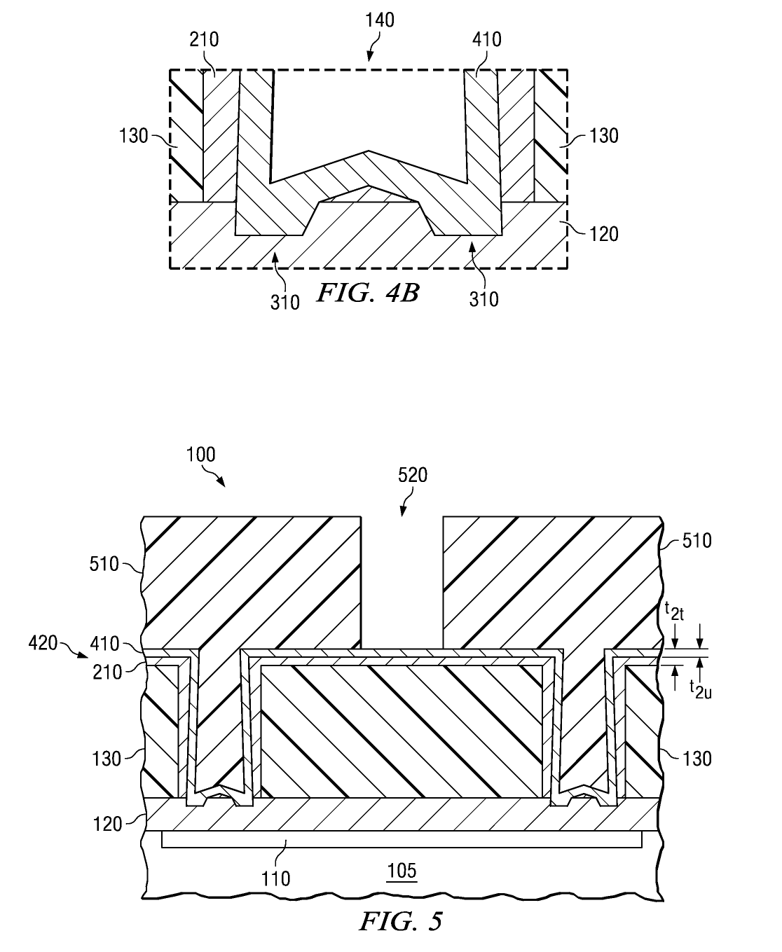

Turning now to FIGS. 4A and 4B, illustrated is the DMD 100 of FIGS. 3A and 3B after forming a second conductive layer 410 over the first conductive layer 210 and within the openings 140. As is illustrated, the second conductive layer 410 contacts the conductive feature 120 exposed by the anisotropic etch, and in one embodiment forms an ohmic contact with the conductive feature 120. The second conductive layer 410 may comprise the same material as the first conductive layer 210, particularly aluminum in the embodiment shown. Nevertheless, the second conductive layer 410 may comprise other materials. In the embodiment shown, the second conductive layer 410 forms a remaining portion of the hinge metal layer.

The second conductive layer 410, in the embodiment shown, has a thickness (t₂ᵤ) on an upper surface of the first spacer layer 130. In one embodiment, the thickness (t₂ᵤ) might range from about 7.5 nm to about 12.5 nm, among others. In a general sense, the thickness (t₂ᵤ) of the second conductive layer 410 should be chosen such that a final total thickness (t₂ₜ) of the first conductive layer 210 and the second conductive layer 410 is within a desirable range.

The second conductive layer 410 illustrated in FIGS. 4A and 4B may be formed using various different processes. For example, the second conductive layer 210 may also be sputter deposited. However, as compared to the formation of the first conductive layer 210, the second conductive layer 410 may be sputter deposited using a longer throw distance target (e.g., as compared to the shorter throw distance target used to form the first conductive layer 210). The longer throw distance target is beneficial in that it is capable of better filling the void 310, and thus forming an ohmic contact. Accordingly, in one embodiment the longer throw distance is set to about 125 mm or greater, and in one particular embodiment around about 150 mm.

After forming the second conductive layer 410 as described above, both the first and second conductive layers 210, 410 may then be patterned into a hinge 420. The process for patterning the first and second conductive layers 210, 410 may vary. For example, in one embodiment the first and second conductive layers 210, 410 are patterned using a chlorine based plasma. Nevertheless, other etch chemistries or plasmas are within the scope of the present invention. After finishing patterning the hinge 420, the partially completed DMD 100 may be subjected to a clean step. For example, the DMD 100 may be subjected to a 60 second develop clean to remove unwanted polymer.

Advantageous to the present invention, the formation of the first conductive layer 210 and the second conductive layer 410, as well as the etching of the first conductive layer 210, may be performed insitu. Accordingly, the DMD 100 need not be removed from the processing tool between forming the first conductive layer 210 and the second conductive layer 410. This benefits the DMD 100 in that little opportunity exists for an oxide or other layer to form on the conductive feature 120 after the anisotropic etch and prior to the formation of the second conductive layer 410. Accordingly, the ability to form an ohmic contact between the conductive feature 120 and the second conductive layer 410 is greatly increased.

Turning now to FIG. 5, illustrated is the DMD 100 of FIGS. 4A and 4B after forming a second spacer layer 510 over the hinge 420. Preferably the second spacer layer 510 is formed by spin depositing a photoresist to a thickness ranging from about 500 nm to about 1500 nm. Thereafter, an opening 520 may be formed within the second spacer layer 510. Conventional patterning and etching techniques may be used to form the opening 520 in the second spacer layer 510, including a process substantially similar to that used to form the openings 140 in the first spacer layer 130. The patterned second spacer layer 510 may then be deep UV hardened to a temperature of around about 175° C. to prevent flow and bubbling during subsequent processing steps.

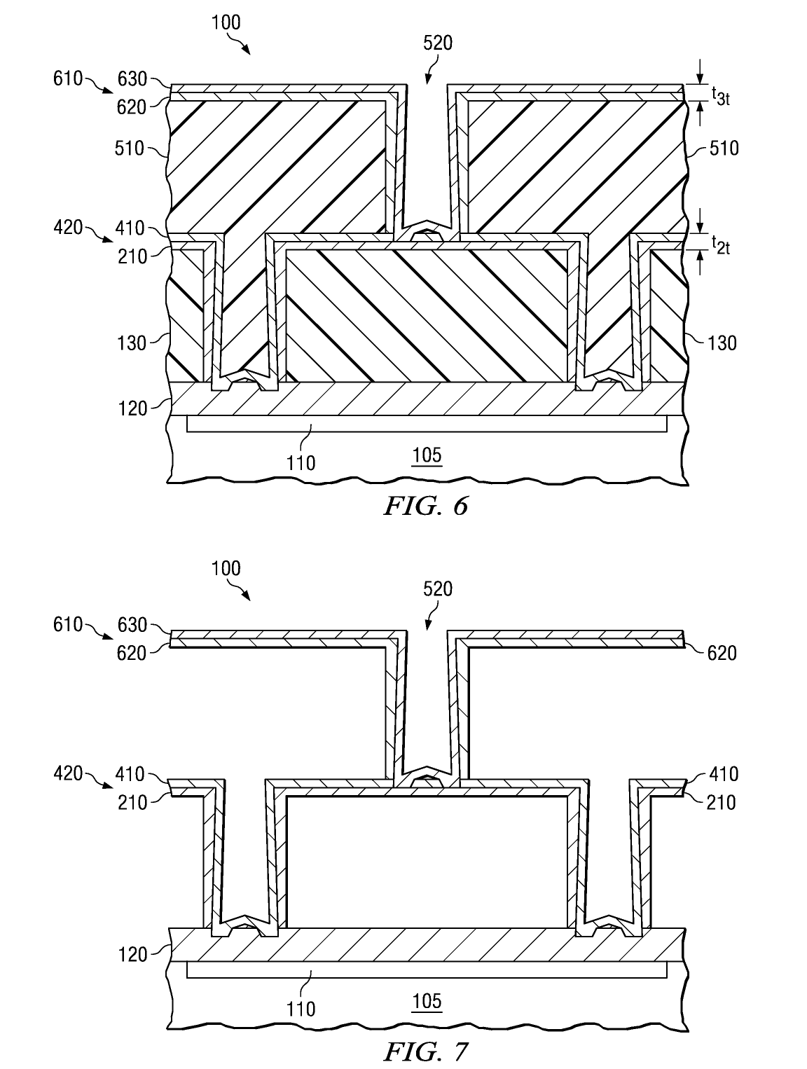

Turning now to FIG. 6, illustrated is the DMD 100 of FIG. 5 after forming a mirror structure 610 over the second spacer layer 510. The mirror structure 610 illustrated in FIG. 6 may include a third conductive layer 620 and a fourth conductive layer 630. In the embodiment shown, the mirror structure 610 may form an ohmic contact with the hinge structure 420.

The third conductive layer 620 and fourth conductive layer 630 may comprise similar materials, as well as be formed using similar processes as used to form the first conductive layer 210 and the second conductive layer 410, respectively. Additionally, the mirror structure 610, in one embodiment, has a thickness (t₃ₜ) ranging from about 200 nm to about 500 nm, and more particularly a thickness ranging from about 300 nm to about 350 nm. Accordingly, one skilled in the art, at least based upon the foregoing description, would understand how to form such layers 620, 630.

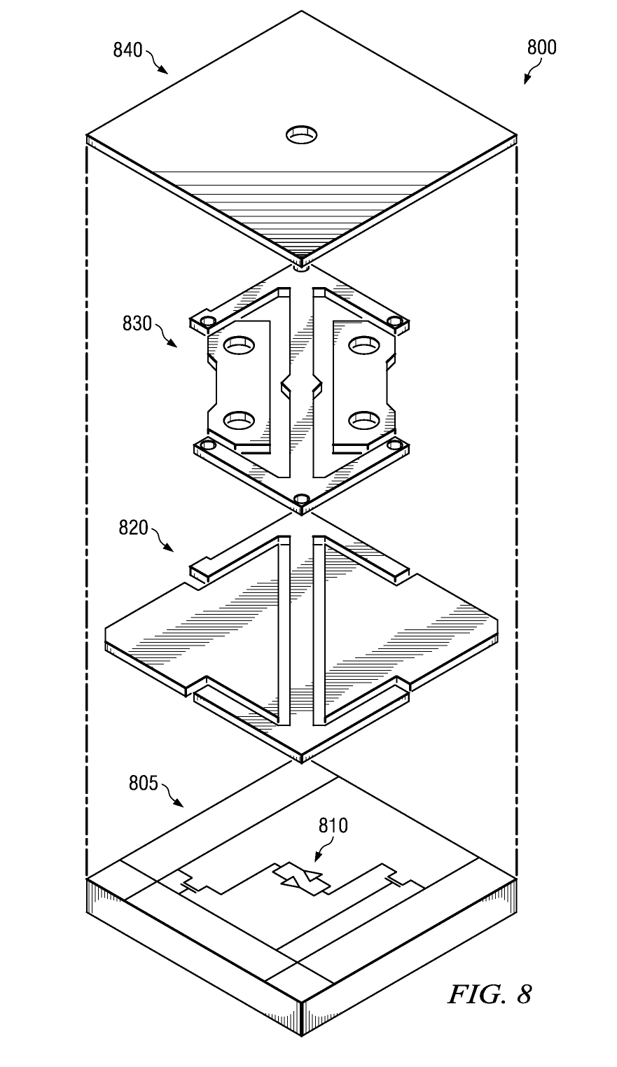

Turning now to FIG. 7, illustrated is the DMD 100 of FIG. 6 after patterning the mirror structure 610 and then removing the first spacer layer 130 and the second spacer layer 510. As those skilled in the art appreciate, an etch mask, such as a plasma-deposited silicon dioxide etch mask, may be used to assist in the etching of the mirror structure 610. Nevertheless, other masks and processes might be used to pattern the mirror structure 610.

The removal of the first spacer layer 130 and of the second spacer layer 510 may be conventional. For example, a conventional downstream plasma ashing or other similar process may be used to remove the first spacer layer 130 and the second spacer layer 510. Nevertheless, other known or hereafter discovered processes could also be used while staying within the scope of the present invention.

It should go without saying that the DMD 100 of FIG. 7 may be but one of an array of such structures that might be located over the substrate 105. For instance, thousands and thousands of such DMD structures 100 are often formed over a single substrate 105. Accordingly, the present invention should not be limited to a single DMD 100 located over a single substrate 105.

Numerous benefits may be achieved using the inventive method for manufacturing a DMD device in accordance with the principles of the present invention. For example, ohmic contacts may be created where they do not currently exist. For instance, a good ohmic contact may be formed between the hinge structure and the conductive feature in DMDs, as well as between the mirror structure and the hinge structure. Moreover, the ohmic contacts may be formed without materially affecting the first and second spacer layers. Additionally, a single tool can be used to insitu form the different layers of the hinge structure and perform the anisotropic etch associated therewith, as well as to insitu form the different layers of the mirror structure and perform the anisotropic etch associated therewith. This process substantially eliminates the opportunity for an oxide or other defect layer to form after the respective anisotropic etches.

Turning now to FIG. 8, illustrated is an exploded view of a completed DMD 800 manufactured in accordance with the principles of the present invention. The DMD 800 illustrated in FIG. 8 includes, among other elements, a substrate 805 having control circuitry 810 located therein or thereon, a patterned conductive feature 820 located over the control circuitry 810, a patterned hinge structure 830 located over the patterned conductive feature 820, and a patterned mirror structure 840 located over the patterned hinge structure 830. The substrate 805, control circuitry 810, patterned conductive feature 820, patterned hinge structure 830, and patterned mirror structure 840 are similar or slight variations of the substrate 105, control circuitry 110, patterned conductive feature 120, patterned hinge structure 420, and patterned mirror structure 610, respectively, illustrated in FIG. 7.

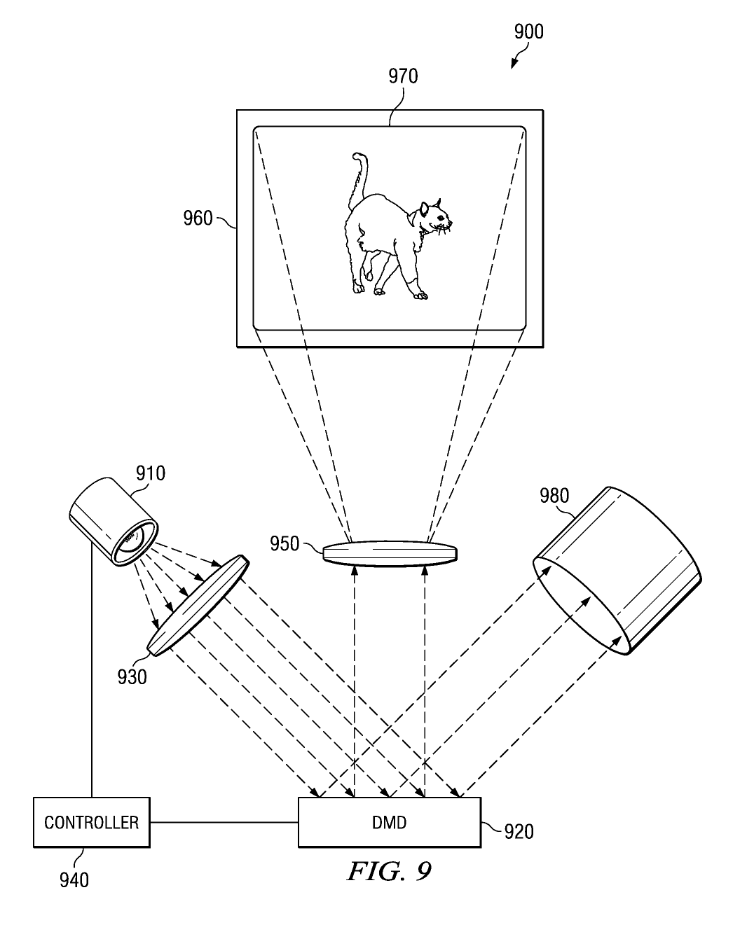

Turning now to FIG. 9, illustrated is a block diagram of a projection display system 900 incorporating DMDs manufactured in accordance with the principles of the present invention. In the projection display system illustrated in FIG. 9, illumination from a light source 910 is focused onto the surface of one or more DMDs 920 by means of a condenser lens 930 placed in the path of the light. An electronic controller 940 is connected to both the DMDs 920 and the light source 910 and used to modulate the DMDs 920 and to control the light source 910.

For all DMD pixels in the ON state, the incoming light beam is reflected into the focal plane of a projection lens 950, where it is magnified and projected on to a viewing screen 960 to form an image 970. On the other hand, DMD pixels in the OFF state, as well as any stray light reflected from various near flat surfaces on and around the DMD, are reflected into a light trap 980 and discarded.

Those skilled in the art to which the invention relates will appreciate that other and further additions, deletions, substitutions and modifications may be made to the described embodiments without departing from the scope of the invention.

What is claimed is:

1. A method for manufacturing a microelectronic device, comprising:
providing a spacer layer over a substrate, the spacer layer having one or more openings therein;
forming a first conductive layer over the spacer layer and within the one or more openings;
subjecting the first conductive layer to an anisotropic etch, the anisotropic etch exposing at least a portion of the substrate within the one or more openings, but leaving the spacer layer substantially covered; and
forming a second conductive layer over the first conductive layer and within the one or more openings, the second conductive layer contacting the substrate exposed by the anisotropic etch.

2. The method as recited in claim 1 wherein the substrate is a conductive feature and further wherein the second conductive layer makes an ohmic contact with the conductive feature.

3. The method as recited in claim 1 wherein the spacer layer comprises a material that is susceptible to a pre-metal deposition clean.

4. The method as recited in claim 3 wherein the spacer layer comprises photoresist.

5. The method as recited in claim 1 wherein the anisotropic etch exposes a ring of the substrate in a bottom and about an inner periphery of the opening.

6. The method as recited in claim 1 wherein a throw target used to form the first conductive layer is less than a throw target used to form the second conductive layer.

7. The method as recited in claim 1 wherein forming the first conductive layer includes forming the first conductive layer such that its thickness in a bottom and about an inner periphery of the opening is less than about 20 percent of its thickness on an upper surface of the spacer layer.

8. The method as recited in claim 1 wherein forming the first conductive layer includes forming the first conductive layer such that its thickness in a bottom and about an inner periphery of the opening ranges from about 2.0 nm to about 4.0 nm and its thickness on an upper surface of the spacer layer ranges from about 15.0 nm to about 25.0 nm.

9. The method as recited in claim 1 wherein the first conductive layer and the second conductive layer comprise a first metal layer and a second metal layer.

10. The method as recited in claim 9 wherein the first metal layer and the second metal layer contain aluminum.

11. The method as recited in claim 1 wherein the first conductive layer and the second conductive layer form at least a portion of a hinge structure for a digital micromirror device.

12. The method as recited in claim 1 wherein the first conductive layer and the second conductive layer form at least a portion of a mirror structure for a digital micromirror device.

13. The method as recited in claim 1 wherein the spacer layer is a first spacer layer and further including;
forming a second spacer layer over the second conductive layer, the second spacer layer having one or more openings therein;
forming a third conductive layer over the second spacer layer and within the one or more openings of the second spacer layer;
subjecting the third conductive layer to a second anisotropic etch, the second anisotropic etch exposing at least a portion of the second conductive layer within the one or more openings in the second spacer layer, but leaving the second spacer layer substantially covered; and
forming a fourth conductive layer over the third conductive layer and within the one or more openings in the second spacer layer, the fourth conductive layer contacting the second conductive layer exposed by the second anisotropic etch.

14. The method as recited in claim 13 further including removing the first and second spacer layers after forming the fourth conductive layer.

15. A microelectronic device, comprising:
a conductive feature;
a first conductive layer located over the conductive feature, wherein at least a portion of the first conductive layer is configured as a well, and further wherein the first conductive layer has a void in a bottom and about an inner periphery of the well; and
a second conductive layer located within the well and substantially filling the void, the second conductive layer configured to form an ohmic contact with the conductive feature.

16. The microelectronic device as recited in claim 15 wherein the void is configured as a ring about an inner periphery of the well.

17. The microelectronic device as recited in claim 15 wherein the first conductive layer and the second conductive layer are a first metal layer and second metal layer containing aluminum.

18. The microelectronic device as recited in claim 15 wherein the first conductive layer and the second conductive layer form at least a portion of a hinge structure for a digital micromirror device.

19. The microelectronic device as recited in claim 15 wherein the first conductive layer and the second conductive layer form at least a portion of a mirror structure for a digital micromirror device.

20. The microelectronic device as recited in claim 15 further including;
a third conductive layer located over the second conductive layer, wherein at least a portion of the third conductive layer is configured as a second well, and further wherein the third conductive layer has a void in a bottom and about an inner periphery of its well; and
a fourth conductive layer located within the second well and substantially filling the void therein, the fourth conductive layer configured to form an ohmic contact with the second conductive layer.
